(19) United States
(12) Patent Application Publication
(10) Pub. No.: US 2025/0301823 A1
(43) Pub. Date: Sep. 25, 2025

(54) PHOTOVOLTAIC CELL AND PHOTOVOLTAIC MODULE

(71) Applicant: LONGI GREEN ENERGY TECHNOLOGY CO., LTD., Xi'an (CN)

(72) Inventors: Zhao WU, Xi'an (CN); Chen XU, Xi'an (CN); Zifeng LI, Xi'an (CN); Junjie XIE, Xi'an (CN)

(21) Appl. No.: 19/231,011

(22) Filed: Jun. 6, 2025

Related U.S. Application Data
(63) Continuation-in-part of application No. 18/036,583, filed on May 11, 2023, now Pat. No. 12,349,501.

(30) Foreign Application Priority Data
Nov. 18, 2020 (CN) 202011296656.4

(51) Int. Cl. H10F 77/70; H10F 71/00; H10F 77/20

(52) U.S. Cl. CPC H10F 77/703; H10F 71/129; H10F 77/215

(57) ABSTRACT

At least one surface of a cell body of a photovoltaic cell includes a first region and a second region that are not overlapped with each other. The first region is configured with a textured structure. The textured structure comprises one or more pyramid or inverted pyramid structures. The second region is configured with a plurality of pits.

### CROSS-REFERENCE TO RELATED APPLICATION

The present disclosure is continuation-in-part application of U.S. patent application Ser. No. 18/036,583, filed on May 11, 2023, which is a 371 application of PCT Patent Application No. PCT/CN2021/131407, filed on Nov. 18, 2021, which claims priority to Chinese Patent Application No. 202011296656.4 filed on Nov. 18, 2020, each of which is incorporated herein by reference in its entirety.

### TECHNICAL FIELD

The present disclosure relates to the field of photovoltaic cells, in particular to a photovoltaic cell, a method for preparing a photovoltaic cell and a photovoltaic module.

### BACKGROUND

Since traditional energy sources are continuously consumed and have negative impact on the environment, solar energy, which is a pollution-free and renewable energy, has been developed and utilized rapidly, especially photovoltaic cells with high conversion efficiency have become the focus of current research.

At present, in order to reduce the reflection of sunlight on the surface of the photovoltaic cell, a texturing process may be used to prepare pyramid and/or inverted pyramid-shaped textured structures on the surface of the photovoltaic cell, so that the photovoltaic cell can absorb more sunlight for photoelectric conversion, and the conversion efficiency of the photovoltaic cell is improved. Such structure has a good anti-reflection effect for direct light or light with a small incident angle. However, for light with a large incident angle, a large portion of the light, after passing through the pyramid and/or inverted pyramid-shaped textured structures on the surface of the photovoltaic cell, will be reflected from the surface of the photovoltaic cell back to the air, and will not participate in the photoelectric conversion of the photovoltaic cell. In the related art, a nanoscale light-trapping structure can be prepared on the surface of the photovoltaic cell through a black silicon process. The nanoscale light-trapping structure has a better light-trapping effect on the light with a large incident angle, thereby improving the photoelectric conversion efficiency of the photovoltaic cell.

However, in the current solution, since the nanoscale light-trapping structure greatly increases the surface area of the monocrystalline silicon in the photovoltaic cell, it is hard to generate a uniform passivation layer on the nanostructure, the recombination rate of non-equilibriums carriers on the surface will increase, which will reduce the photoelectric conversion efficiency of the photovoltaic cell.

### SMICRONSMARY

The present disclosure provides a photovoltaic cell and a photovoltaic module.

In a first aspect, an embodiment of the present disclosure provides a photovoltaic cell, including:
a cell body;
at least one surface of the cell body includes a first region and a second region that are not overlapped with each other;
the first region is configured as a textured structure; and
the second region is configured as a plurality of pits.

In some embodiments, a projection size of each of the plurality of pits on the surface of the cell body is 0.5 to 500 microns; and/or a deviation angle between a sidewall of each of the plurality of pits and a thickness direction of the cell body ranges from 0 to 70 degrees.

In some embodiments, the plurality of pits is distributed in an array on the surface of the cell body, and a space between adjacent pits in the plurality of pits is greater or equal to 0, and smaller or equal to 300 microns.

In some embodiments, a ratio of the projection area of the plurality of pits on the surface of the cell body to a surface area of the cell body is 0.4 to 0.95.

In some embodiments, depths of the plurality of pits is greater than or equal to 0.1 micron.

In some embodiments, the plurality of pits includes any one or more of round holes, rectangular holes or holes with irregular shapes.

In some embodiments, the photovoltaic cell includes a silicon wafer substrate. The silicon wafer substrate has a thickness ranging from 50 to 150 microns.

In some embodiments, the photovoltaic cell includes a first electrode on a side of the silicon wafer substrate. The first electrode is at least partially disposed on the textured structure.

In some embodiments, the first electrode includes a first main grid and a first fine grid, the first main grid being disposed on at least one of the textured structures and the plurality of pits, and the first fine grid being disposed on the textured structure.

In some embodiments, the photovoltaic cell further includes a passivation layer disposed on the textured structure as well as bottom surfaces and sidewalls of the pits.

In some embodiments, the first electrode includes a first main grid and a first fine grid, the first main grid is disposed on the textured structure and/or the pits, and the first fine grid is disposed on the textured structure.

In some embodiments, the photovoltaic cell is a photovoltaic cell with single-sided electrodes, and the cell body includes: a silicon wafer substrate; a first passivation layer and a first functional layer arranged on a side of the silicon wafer substrate; and a second passivation layer, a second functional layer, a first electrode and a second electrode arranged on the other side of the silicon wafer substrate.

In some embodiments, a first collection layer and a first transport layer are arranged between the third electrode and the second passivation layer, the first collection layer is disposed on a side of the second passivation layer facing away from the silicon wafer substrate, and the first transport layer is disposed on a side of the first collection layer facing away from the second passivation layer. A second collection layer and a second transport layer are arranged between the fourth electrode and the second passivation layer, the second collection layer is disposed on the side of the second passivation layer facing away from the silicon wafer substrate, and the second transport layer is disposed on a side of the second collection layer facing away from the second passivation layer.

In some embodiments, a thickness of a part of the passivation layer on the sidewalls of the plurality of pits is H1, a thickness of a part of the passivation layer on the bottom surfaces of the plurality of pits is H2, and a thickness of a part of the passivation layer on the first region is H3. H2 for at least one position is greater than H1 for at least one position, and/or, H3 for at least one position is greater than H1 for at least one position.

In some embodiments, each of the plurality of pits has a bottom surface and a sidewall surrounding the bottom surface, and at least a part of the sidewall is inclined relative to the bottom surface. A maximum size of an opening of the plurality of pits is W1, a maximum size of the bottom surface of the plurality of pits is W2, and a maximum depth of the plurality of pits is H, in at least one of the plurality of pits, 0.1≤(W1−W2)/H≤50.

In some embodiments, a one-dimensional size of the pyramid and/or inverted pyramid structures is smaller than a one-dimensional size of the plurality of pits. In at least one of the plurality of pits, one part of the sidewall close to the opening also has pyramid and/or inverted pyramid structures, and there is no pyramid and/or inverted pyramid structures on the other part of the sidewall close to the bottom surface. Or, in at least one of the plurality of pits, all of the side wall has pyramid and/or inverted pyramid structures.

In some embodiments, a one-dimensional size of apart of the pyramid and/or inverted pyramid structures on at the sidewall in at least one of the plurality of pits is D2. A one-dimensional size of a part of the pyramid and/or inverted pyramid structures on at the bottom surface in at least one of the plurality of pits is D1, D2>D1. And/or, a one-dimensional size of the pyramid and/or inverted pyramid structures in the first region is D3; D2>D3.

In some embodiments, along an extension direction of the sidewall of each of the plurality of pits, among all the pyramid and/or inverted pyramid structures corresponding to the sidewall of at least one of the plurality of pits, a one-dimensional size of the pyramid and/or inverted pyramid structures far from the bottom surface is smaller than a one-dimensional size of the pyramid and/or inverted pyramid structures close to the bottom surface.

In some embodiments, in at least one of the plurality of pits, there is no pyramid and/or inverted pyramid structures on a part of the sidewall, the part of the sidewall being parallel to a sidewall of at least one pyramid and/or inverted pyramid structures on the other part of the sidewall.

In some embodiments, the cell body has a first surface and a second surface, the first region and the second region being in the first surface, the first surface having a first edge and a second edge, where a length of the first edge is L1, a length of the second edge is L2, L1≥L2. A region without any of the plurality of pits is an edge region, the edge region including a first edge region and a second edge region intersecting with the first edge region, the first edge region being defined along the first edge, and the second edge region being defined along the second edge. A width of the first edge region is A, and a thickness of the silicon wafer substrate is B, 0.05≤A/B≤40.

In a second aspect, an embodiment of the present disclosure provides a method for preparing the above-mentioned photovoltaic cell.

In a third aspect, an embodiment of the present disclosure provides a photovoltaic module including the above-mentioned photovoltaic cell.

### BRIEF DESCRIPTION OF THE DRAWINGS

In order to more clearly illustrate technical solutions of the embodiments of the present disclosure, accompanying drawings used in the embodiments will be briefly introduced below. It should be understood that the following drawings only show some embodiments of the present disclosure, and should not be regarded as limiting the scope. For those skilled in the art, other related drawings may be obtained based on these drawings without paying creative labor.

FIG. 1 is a schematic structural diagram illustrating a photovoltaic cell provided by an embodiment of the present disclosure;

FIG. 2 is a top view of a photovoltaic cell provided by an embodiment of the present disclosure;

FIG. 3 is a schematic structural diagram illustrating a photovoltaic cell with double-sided electrodes provided by an embodiment of the present disclosure;

FIG. 4 is a schematic structural diagram illustrating a photovoltaic cell with single-sided electrodes provided by an embodiment of the present disclosure;

FIG. 5 is a schematic longitudinal sectional view of a pit in a photovoltaic cell provided in an embodiment of the present disclosure;

FIG. 6 is a schematic longitudinal sectional view of a pit in a photovoltaic cell provided in an embodiment of the present disclosure;

FIG. 7 is a schematic longitudinal sectional view of a pit in a photovoltaic cell provided in an embodiment of the present disclosure;

FIG. 8 is an enlarged SEM image of a local area of a pit in a photovoltaic cell provided in an embodiment of the present disclosure;

FIG. 9 is a schematic diagram of the first surface structure of a silicon wafer provided in an embodiment of the present disclosure;

FIG. 10 is a flowchart of a method for preparing a photovoltaic cell provided by an embodiment of the present disclosure;

FIG. 11 is a flowchart of a method for preparing a photovoltaic cell with double-sided electrodes provided by an embodiment of the present disclosure; and

FIG. 12 is a flowchart of a method for preparing a photovoltaic cell with single-sided electrodes provided by an embodiment of the present disclosure.

### DETAILED DESCRIPTION OF THE EMBODIMENTS

The technical solutions of the embodiments of the present disclosure will be clearly and thoroughly described below with reference to the accompanying drawings of the embodiments of the present disclosure. Apparently, only a part of the embodiments, not all the embodiments of the present disclosure, are described. All other embodiments obtained, based on the embodiments described in the present disclosure, by those skilled in the art without paying creative efforts shall fall within the protection scope of the present disclosure.

In order to reduce the reflection of incident light on the surface of the photovoltaic cell, improve the absorption effect of incident light, and increase the power generation capacity, the photovoltaic cell is usually designed with a textured structure with pyramid structures and inverted pyramid structures on the surface. The textured structure has a good anti-reflection effect for vertical incident light or incident light with a small incident angle, which can reduce the probability of the incident light with a small angle being reflected out of the photovoltaic cell, while the textured structure has bad effect for incident light with a large incident angle. That is, the omnidirectionality of the photovoltaic cell is not good, and the photovoltaic cell with poor omnidirectionality needs to be disposed at the optimal light receiving angle or use a tracking bracket to achieve a large power generation capacity. Since the optimal light receiving angle changes according to geographical locations, time and seasons, etc., a fixed bracket cannot be adjusted in real time so that the photovoltaic cell reaches the optimal light receiving angle, and the tracking bracket is usually expensive. Therefore, a simple manner for increasing the power generation capacity is improving the omnidirectionality of the photovoltaic cell.

A photovoltaic cell and a photovoltaic module provided by the present disclosure will be described in detail below by enumerating several specific embodiments.

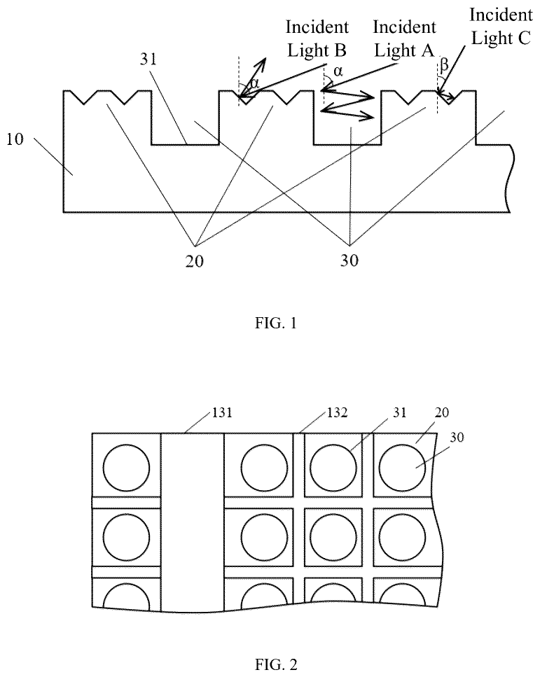

Reference is made to FIG. 1, which is a schematic structural diagram illustrating a photovoltaic cell provided by an embodiment of the present disclosure. As shown in FIG. 1, the photovoltaic cell includes a cell body 10, at least one surface of which includes a first region 20 and a second region 30. The first region 20 is configured with a textured structure, and the second region 30 is configured with a plurality of pits 31.

That is, in some embodiments, the first region 20 and the second region 30 are only defined in the light receiving surface of the cell body. In other embodiments, the first region 20 and the second region 30 are only defined in the back surface of the cell body. In other embodiments, the first region 20 and the second region 30 are defined in both the light receiving surface and the back surface of the cell body.

The first region with the textured structure is composed of pyramid and/or inverted pyramid structures distributed along the surface of the cell body. The cell body can be prepared from a monocrystalline silicon wafer. Accordingly, the textured structure is a regular or irregular pyramid and/or inverted pyramid structure prepared on the surface of the monocrystalline silicon wafer through a texturing process. The cell body can also be prepared from a polycrystalline silicon wafer. Accordingly, the textured structure is a regular or irregular pyramid and/or inverted pyramid structure prepared on the surface of the polycrystalline silicon wafer through a texturing process.

In the embodiment of the present disclosure, the surface of the cell body may be a light receiving surface of the cell body, that is, the surface that is directly in contact with the incident light. At the same time, incident light with an incident angle greater than or equal to 45 degrees can be referred to as large-angle incident light. Referring to FIG. 1, the incident angle of the incident light B is α, and α is greater than 45 degrees, that is, the incident light B is a large-angle incident light. The incident light B is irradiated on the first region 20 with a textured structure on the surface of the photovoltaic cell, reflected by the pyramid and/or inverted pyramid structures in the textured structure, and emitted in a direction away from the photovoltaic cell after one reflection. Therefore, the incident light B has a very short optical path in the photovoltaic cell, resulting in poor absorption effect of the photovoltaic cell on the incident light B.

Further, incident light with an incident angle less than 45 degrees can be referred to as small-angle incident light. Referring to FIG. 1, the incident angle of the incident light C is β, and β is less than 45 degrees, that is, the incident light C is a small-angle incident light. The incident light C is irradiated on the first region 20 with the textured structure on the surface of the photovoltaic cell, and reflected by the pyramid and/or inverted pyramid structures in the textured structure, it can undergo multiple reflections in the textured structure of the photovoltaic cell. Therefore, the incident light C has a longer optical path in the photovoltaic cell, resulting in better absorption effect of the photovoltaic cell on the incident light C.

As can be seen, the photovoltaic cell with merely the textured structure has a good absorption effect for the small-angle incident light, but has a poor absorption effect for the large-angle incident light. Therefore, the omnidirectionality of the photovoltaic cell is not good. When a photovoltaic module including such photovoltaic cell is installed in an aircraft, an automobile and a building, the photovoltaic cell needs to have the optimum light receiving angle so that the installation position is limited, or a tracking bracket is necessary to achieve a large power generation capacity, resulting in relatively high cost.

In addition, the surface of the cell body of the photovoltaic cell also includes the second region configured with a plurality of pits. The projection size of each of the pits on the surface of the cell body is 0.5 to 500 microns, that is, each of the pits is a micron-scale pit. Further, a deviation angle between the sidewall of the pit and a thickness direction of the cell body is less than 60 degrees, so that the small-angle incident light irradiates into the pit and is reflected for multiple times in the pit.

Referring to FIG. 1, the surface of the cell body 10 of the photovoltaic cell also includes the second region 30 configured with a plurality of micron-scale pits 31, and the deviation angle between the sidewall of the pit 31 and the thickness direction of the cell body 10 is 0 degrees.

The shape of the micron-scale pits 31 can be any one or more of a circular hole, a rectangular hole or an irregular shape. If the shape of the micron-scale pit 31 is a circular hole, then the diameter of the micron-scale pit 31 ranges from 0.5 to 500 microns. If the shape of the micron-scale pit 31 is a rectangular hole or an irregularly shaped deep hole, the length of the diagonal line of the micron-scale pit 31 ranges from 0.5 to 500 microns.

Specifically, the incident light A is also a large-angle incident light with an incident angle α. When irradiating a micron-scale pit 31 on the surface of the photovoltaic cell, the incident light A is reflected by the sidewall and the bottom surface of the micron-scale pit 31, and can undergo multiple reflections in the micron-scale pit 31 of the photovoltaic cell. Therefore, the incident light A has a longer optical path in the photovoltaic cell, and the absorption effect of the photovoltaic cell on the incident light A is better.

As can be seen, for a photovoltaic cell with a textured structure and micron-scale pits in the cell body, the textured structure has a better absorption effect for small-angle incident light, and the micron-scale pits can improve the absorption effect of the photovoltaic cell for the small-angle incident light, moreover, micron-sized pits have a good absorption effect for large-angle incident light. Therefore, such photovoltaic cell has high omnidirectionality. When a photovoltaic module including such photovoltaic cell is installed in aircrafts, automobiles and buildings, the photovoltaic cell can have better absorption effect for the incident light without adjusting installation location and using a tracking bracket, thereby improving the photoelectric conversion efficiency of the photovoltaic module, and achieving a greater power generation capacity.

Further, the projection size of the micron-scale pit on the surface of the cell body is 0.5 to 500 microns, that is, the structure size of the micron-scale pit is larger relative to the nanoscale light-trapping structure, which can avoid that the passivation layer cannot be successfully prepared on the smaller nanoscale light-trapping structure, thereby ensuring that a uniform passivation layer can be effectively generated on the surface of the photovoltaic cell. Moreover, the surface area of the photovoltaic cell with micron-scale pits is small, so the specific surface area of the photovoltaic cell can be reduced. Accordingly, the recombination rate of non-equilibriums carriers on the surface of the photovoltaic cell is reduced without affecting the lateral transmission and collection of carriers on the surface of the photovoltaic cell, and the photoelectric conversion efficiency of the photovoltaic cell is ultimately improved.

In the embodiment of the present disclosure, the photovoltaic cell includes a cell body; at least one surface of the cell body includes a first region and a second region; the first region is configured with a textured structure; the second region is configured with a plurality of pits. The projection size of each of the pits on the surface of the cell body is 0.5 to 500 microns; the deviation angle between the sidewall of each of the pits and the thickness direction of the cell body is less than 15 degrees. In the present disclosure, at least one surface of the cell body of the photovoltaic cell includes the first region and the second region, among them, the first region is configured with the textured structure composed of pyramid and/or inverted pyramid structures, for incident light with a small incident angle, the textured structure can reduce the probability of the incident light with a small angle being reflected out of the photovoltaic cell; the second region is configured with a plurality of pits with a projection size of 0.5 to 500 microns on the surface of the cell body, and the deviation angle between the sidewall of the pit and the thickness direction of the cell body is less than 60 degrees, for incident light with a large incident angle, the micron-scale pits on the surface of the photovoltaic cell can reduce the probability of the large-angle incident light being reflected out of the photovoltaic cell, the large-angle incident light is reflected for multiple times in the micron-scale pits, and has a long optical path in the photovoltaic cell, which can improve the absorption effect of the photovoltaic cell on the incident light. Moreover, compared with the nanoscale light-trapping structure, the structure size of the micron-scale pit is larger, and the surface area of the photovoltaic cell with the micron-scale pits is smaller. Therefore, a uniform passivation layer can be effectively formed on the surface of the photovoltaic cell, moreover, the recombination rate of non-equilibriums carriers on the surface of the photovoltaic cell can be reduced, thereby improving the photoelectric conversion efficiency of the photovoltaic cell.

In some embodiments, the projection size of each of the pits on the surface of the cell body is 200 microns, so as to ensure that the pits arranged in the second region on the surface of the cell body are relatively uniform and moderate in size.

In some embodiments, reference is made to FIG. 2, which is a top view of a photovoltaic cell provided by an embodiment of the present disclosure. As shown in FIG. 2, a plurality of micron-scale pits 31 may be distributed in an array on the surface of the cell body, and a space between adjacent micron-scale pits 31 may be 0 to 300 microns, so that other structures of the photovoltaic cell can be arranged, between adjacent micron-scale pits 31, on the textured structure in the first region 20 to realize the function of the photovoltaic cell.

In some embodiments, each of the pits includes any one or more of a circular hole, a rectangular hole, or has an irregular shape, so that the incident light are reflected for multiple times when the incident light irradiates on the bottom surface and sidewalls of the micron-scale pit. Referring to FIG. 2, the micron-scale pits 31 are circular holes.

In some embodiments, depths of the pits are greater than or equal to 0.1 micron, and a ratio of the projection area of the micron-scale pits on the surface of the cell body to the surface area of the cell body may be 0.4 to 0.95.

In the embodiment of the present disclosure, the depth of the micron-scale pit and the ratio can be determined according to the specific application scenario of the photovoltaic module including the photovoltaic cell. Specifically, for application scenarios where large-angle incident light accounts for a large proportion, the projection size of the pits on the surface of the cell body can be increased, or the number of the pits can be increased, so that the ratio of the projection area of the pits are on the surface of the cell body to the surface area of the cell body is larger, thereby increasing the absorption effect of the photovoltaic cell for large-angle incident light; for application scenarios where large-angle incident light accounts for less proportion, the projection size of the pits on the surface of the cell body can be reduced, or the number of the pits can be reduced, so that the ratio of the projection area of the pits on the surface of the cell body to the surface area of the cell body is smaller, thereby enabling the photovoltaic cell to have a better absorption effect on the incident light.

Further, when the incident angle of the large-angle incident light is large, the micron-scale pits with a smaller depth can also make the incident light be reflected for multiple times in the micron-scale pits, so the depth of the micron-scale pits can be reduced; when the incident angle of the large-angle incident light is small, only micron-scale pits with a larger depth can ensure multiple reflections of the incident light in the micron-scale pits, thus it is necessary to increase the depth of the micron-scale pits.

In some embodiments, the cell body may include a first electrode that is at least partially disposed on the textured structure, that is, the first electrode cannot be completely disposed on the micron-scale pits, thereby reducing the filling of the first electrode on the micron-scale pits, avoiding affecting the light trapping function of the micron-scale pits for large-angle reflection light.

In some embodiments, the photovoltaic cell may further include a passivation layer that is disposed on the textured structure as well as the bottom surfaces and the sidewalls of the pits. Compared with the nanoscale light-trapping structure, the structure size of the micron-scale pits is larger, and the surface area of the photovoltaic cell with the micron-scale pits is small, so a uniform passivation layer can be effectively generated on the surface of the photovoltaic cell, realizing the surface passivation of the photovoltaic cell.

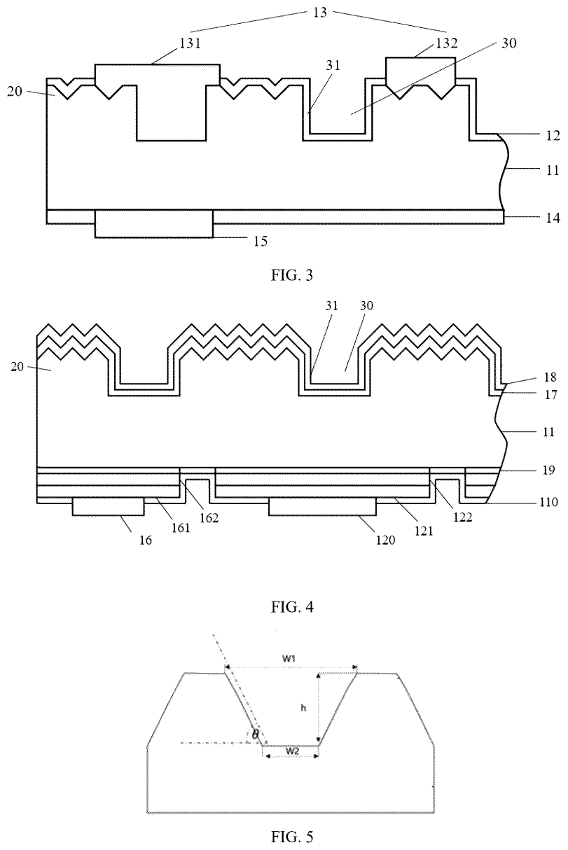

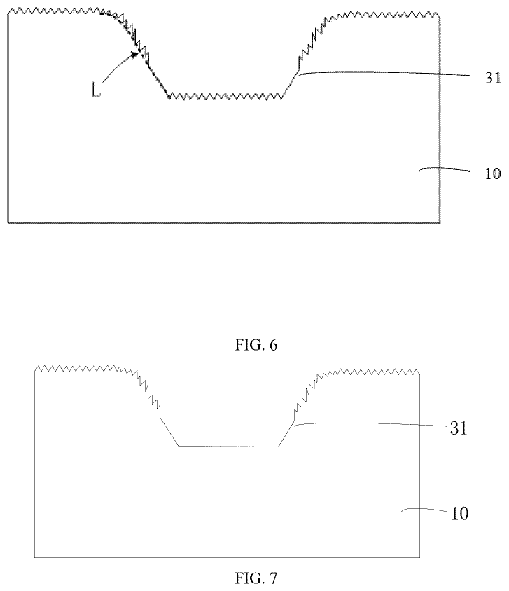

In some embodiments, the photovoltaic cell in the embodiment of the present disclosure may be a photovoltaic cell with double-sided electrodes, such as a passivated emitter and rear cell (PERC), or a tunnel oxide passivated contact (TOPCon) photovoltaic cell. Reference is made to FIG. 3, which is a schematic structural diagram illustrating a photovoltaic cell with double-sided electrodes provided by an embodiment of the present disclosure. As shown in FIG. 3, the cell body includes a silicon wafer substrate 11, a first electrode 13 and a first functional layer 12 arranged on one side of the silicon wafer substrate 11, and a second functional layer 14 and a second electrode 15 arranged on the other side of the silicon wafer substrate 11.

The first functional layer 12 is disposed on the textured structure in the first region 20 and the bottom surfaces and the sidewalls of the pits 31 in the second region 30, and the first functional layer 12 has a first hollow structure where the first electrode 13 is located. The second functional layer 14 is disposed on the other side of the silicon wafer substrate 11, and the second functional layer 14 has a second hollow structure where the second electrode 15 is located.

Specifically, the silicon wafer substrate may be an n-type silicon wafer substrate prepared from an n-type crystalline silicon wafer. The first functional layer may be a multilayer structure, for example, the first functional layer may include 2-nanometer-thick silicon oxide and 70-nanometer-thick silicon nitride, which is respectively used for surface passivation and antireflection on one side of the photovoltaic cell. The second functional layer may also be a multilayer structure, for example, the second functional layer may include 2-nanometer-thick silicon oxide, 15-nanometer-thick aluminum oxide, and 50-nanometer-thick silicon nitride, thereby realizing the surface passivation and anti-reflection function on the other side of the photovoltaic cell.

Further, the first electrode is provided on one side of the silicon wafer substrate, and the second electrode is provided on the other side of the silicon wafer substrate, thereby forming a photovoltaic cell with double-sided electrodes. Specifically, a mask may be used to prepare the first hollow structure on the first functional layer, and the first electrode is located at the first hollow structure, so that the first electrode may be disposed on the textured structure or in the pits. Further, a mask may be used to prepare the second hollow structure on the second functional layer, and the second electrode is located at the second hollow structure, so that the second electrode is disposed on the other side of the silicon wafer substrate.

In some embodiments, referring to FIG. 3, the first electrode 13 may include a first main grid 131 and a first fine grid 132, among them, the first main grid 131 may be disposed on the textured structure in the first region 20 and/or the pits 31 in the second region 30, and the first fine grid 132 may be disposed on the textured structure.

Specifically, for photovoltaic cells, the main function of the first fine grid(s) is to collect the current generated by a photovoltaic cell and transfer the current to the first main grid(s), so that multiple photovoltaic cells can use the first main grids to gather the current generated by the multiple photovoltaic cells, and transfer the current to a junction box to provide power to external equipment. There is a large quantity of first fine grids and the first fine grid is relatively small in width, thus referring to FIG. 2, the first fine grids 132 can be disposed on the textured structure between adjacent pits 31. On the contrary, there are a little quantity of first main grids and the first main grid is relatively large in width, thus the first main grid 131 can be disposed in the pit 31, or disposed on the textured structure between adjacent pits 31, or disposed both in the pit 31 and on the textured structure, so that the structure of the photovoltaic cell is more compact, and the photoelectric conversion efficiency of the photovoltaic cell is improved.

In some embodiments, the photovoltaic cell in the embodiment of the present disclosure may be a photovoltaic cell with single-sided electrodes, for example a polycrystalline silicon on oxide passivating contact (POLO) cell, an interdigitated back contact (IBC) cell, a silicon heterojunction (SHJ) cell. Reference is made to FIG. 4, which is a schematic structural diagram illustrating a photovoltaic cell with single-sided electrodes provided by an embodiment of the present disclosure, as shown in FIG. 4, the cell body includes: a silicon wafer substrate 11; a first passivation layer 17 and a third functional layer 18 disposed on a side of the silicon wafer substrate 11; and a second passivation layer 19, a fourth functional layer 110, a third electrode 16 and a fourth electrode 120 disposed on the other side of the silicon wafer substrate 11.

The textured structure in the first region 20 is disposed on one surface of the silicon wafer substrate 11, the bottom surfaces of the pits 31 are arranged in the silicon wafer substrate. The first passivation layer 17 is disposed on the textured structure as well as the bottom surfaces and sidewalls of the pits 31, and the third functional layer 18 is disposed on a side of the first passivation layer 17 facing away from the silicon wafer substrate 11. The second passivation layer 19 is disposed on the other side of the silicon wafer substrate 11, and the fourth functional layer 110 is disposed on a side of the second passivation layer 19 facing away from the silicon wafer substrate 11. The fourth functional layer 110 has a third hollow structure, and the third electrode 16 and the fourth electrode 120 are alternatively arranged in the third hollow structure.

Specifically, the silicon wafer substrate may be an n-type silicon wafer substrate prepared from an n-type crystalline silicon wafer; the first passivation layer can be amorphous silicon or silicon oxide, so as to achieve a surface passivation on one side of the photovoltaic cell; the third functional layer may be a multi-layer structure, for example, a multi-layer silicon nitride structure with a total thickness of 70 nanometers, so as to achieve a surface field passivation and anti-reflection function on one side of the photovoltaic cell; the second passivation layer may be amorphous silicon or silicon oxide, so as to achieve a surface passivation on the other side of the photovoltaic cell; and the fourth functional layer can achieve the surface field passivation and anti-reflection function on the other side of the photovoltaic cell.

Further, the third electrode and the fourth electrode are provided on the other side of the silicon wafer substrate, thereby forming a photovoltaic cell with single-sided electrodes. Specifically, a mask is used to prepare the third hollow structure on the fourth functional layer, so that the third electrode and the fourth electrode are alternatively arranged in the third hollow structure.

In some embodiments, referring to FIG. 4, a first collection layer 162 and a first transport layer 161 are arranged between the third electrode 16 and the second passivation layer 19, the first collection layer 162 being disposed on a side of the second passivation layer 19 facing away from the silicon wafer substrate 11, the first transport layer 161 being disposed on a side of the first collection layer 162 facing away from the second passivation layer 19; a second collection layer 122 and a second transport layer 121 are arranged between the fourth electrode 120 and the second passivation layer 19, the second collection layer 122 being disposed on a side of the second passivation layer 19 facing away from the silicon wafer substrate 11, the second transport layer 121 being disposed on a side of the second collection layer 122 facing away from the second passivation layer 19.

Specifically, when an n-type crystalline silicon wafer is used as the silicon wafer substrate, the first collection layer may be a majority carrier collection region composed of n-type doped amorphous silicon, and the second collection layer may be a minority carrier collection region composed of p-type doped amorphous silicon. The first collection layer and the second collection layer are alternatively arranged on the surface of the second passivation layer on the other side of the silicon wafer substrate. Correspondingly, the first transport layer is a carrier transport layer corresponding to the first collection layer, that is, a majority carrier transport layer, the third electrode is a majority carrier terminal electrode of a photovoltaic cell with single-sided electrodes; the second transport layer is a carrier transport layer corresponding to the second collection layer, that is, a minority carrier transport layer, the fourth electrode is a minority carrier terminal electrode of a photovoltaic cell with single-sided electrodes.

In some embodiments, as shown in FIG. 5, when the maximum size W1 of the opening corresponding to the pit 31 is greater than the maximum size W2 of the bottom surface of the pit 31, at least a part of the sidewall of the pit 31 is inclined relative to the bottom surface to reduce the difficulty of manufacturing the pit 31 and improve the light trapping effect of the pit 31. In this case, it can be understood that when the maximum depth h of the pit 31 is fixed, the difference between the maximum size W1 of the opening corresponding to the pit 31 and the maximum size W2 of its own bottom surface will affect the degree of height change of the part of the sidewall of the pit 31 that is inclined relative to the bottom surface, that is, the degree of inclination of the inclined portion, and thus affect its own light trapping effect, as well as the passivation effect of the passivation layer on the pit 31 when applying the silicon wafer substrate 10 provided by the embodiment of the present disclosure to photovoltaic cells. Therefore, the size of pit 31 at the opening and bottom, as well as the relationship between different sizes, can be determined based on the requirements for the light trapping effect of pit 31 in practical application scenarios, as well as the requirements for the passivation effect of the passivation layer at pit 31.

The maximum depth corresponding to a pit is defined as h. Based on this, in some embodiments, 0.1≤(W1−W2)/h≤50 can be satisfied in at least one pit. In this way, the height variation of the inclined portion of the sidewall of the pit relative to the bottom surface is relatively gentle, that is, the degree of inclination of the inclined portion in the sidewall is relatively large. Therefore, when applying the silicon wafer substrate 10 to a photovoltaic cell and manufacturing a passivation layer on the first and/or second surface of the silicon wafer substrate 10 with pits. The gentle height variation of the sidewall of the pit 31 is conducive to allowing the carrier gas used for depositing the passivation layer to smoothly enter deeper regions of the pit 31 and come into contact with more different part of the sidewall and the bottom surface of the pit 31. That is, the lateral and longitudinal flow resistance of the carrier gas at the pit 31 is reduced, the flow field is smoother, and it is conducive to eliminating flow field anomalies, thereby improving the formation quality of the passivation layer in the pit 31, enabling the passivation layer to fully deposit in different part of the sidewall and the bottom surface of the pit 31. In this way, the passivation contact area between the pit and the passivation layer is increased, which improves the passivation effect of the passivation layer.

For example, the value of (W1−W2)/h may be 0.1, 1, 5, 8, 10, 15, 20, 25, 30, 35, 40, 45, or 50.

In some embodiments, W1 is greater than or equal to 0.5 micron and less than or equal to 500 microns. For example, W1 may be 0.5 micron, 30 microns, 50 microns, 80 microns, 100 microns, 150 microns, 200 microns, 300 microns, 350 microns, 400 microns, 450 microns or 500 microns, etc. In this case, it is beneficial to prevent the difficulty of the carrier gas used for depositing the passivation layer from entering the bottom of the pit 31 due to the small size of W1, and to prevent the difference between W1 and W2 from being too small when the maximum depth of the pit 31 is fixed. It is conducive to making the height change of the part of the sidewall of the pit 31 that is inclined relative to the bottom relatively gentle, so that the carrier gas used for depositing the passivation layer can smoothly enter deeper regions of the pit and contact with more different part of the sidewall and the bottom surface of the pit 31, thereby improving the quality of the passivation layer formation in the pit and allowing the passivation layer to fully deposit in different parts of the sidewall and the bottom surface of the pit 31, increasing the passivation contact area between the two and enhancing the passivation effect of the passivation layer. In addition, it can also prevent poor light trapping effect due to the sidewall being tilting too much due to excessive W1, which improves the light utilization efficiency of the silicon wafer substrate 10.

In some embodiments, W2 is greater than or equal to 0.5 micron and less than or equal to 100 microns. For example, W2 may be 0.5 micron, 5 microns, 10 microns, 15 microns, 20 microns, 30 microns, 50 microns, 60 microns, 80 microns, 90 microns, or 100 microns. In this case, it can be understood that, with the maximum size W1 and maximum depth h fixed at the opening corresponding to the pit 31, the larger the maximum size W2 at the bottom, the smaller the difference between W1 and W2, and the steeper the portion of the sidewall that is inclined relative to the bottom surface. On the contrary, the smaller W2, the greater the difference between W1 and W2, and the smaller the slope of the part of the sidewall that is inclined relative to the bottom surface. Based on this, W2 is within the above range, which is conducive to preventing the height change of the inclined part of the sidewall relative to the bottom surface from being too gentle due to W2 being too small, and improving the light trapping effect of the pit. In addition, it can also prevent the slope of the inclined part of the sidewall relative to the bottom surface from being too large due to excessive W2, which is conducive to reducing the lateral and longitudinal flow resistance at the pit, eliminating flow field anomalies, improving the quality of passivation layer formation in the pit, and allowing the passivation layer to fully deposit in different part of the sidewall and the bottom surface of the pit 31, increasing the passivation contact area between the two and enhancing the passivation effect of the passivation layer.

In some embodiments, 0 micron≤W1−W2≤499.5 microns. For example, the difference between W1 and W2 may be 0 micron, 29 microns, 35 microns, 40 microns, 49 microns, 50 microns, 60 microns, 80 microns, 100 microns, 200 microns, 300 microns, 400 microns or 499.5 microns, etc. The application principle of the beneficial effects in this situation can refer to the application principle of the beneficial effects with W1 greater than or equal to 30 μm and less than or equal to 500 microns described earlier, which will not be repeated here.

In one of the plurality of pits 31, the length of the sidewall is L, and an included angle between the sidewall and the bottom surface is θ. Based on this, in some embodiments, for at least one pit 31, h<L≤50×h÷sin θ. In this case, in at least one pit 31, a ratio of the length L of the sidewall to the maximum depth h is within the above range, which is conducive to preventing the slope of the part of the sidewall of the pit 31 that is inclined relative to the bottom surface from being too small due to the ratio being too large (i.e., L is larger when h is constant), resulting in poor light trapping effect of the sidewall of the pit 31 for light with large incident angle. This is beneficial for improving the high light trapping effect of the first and/or second surfaces for large angle incident light. In addition, it can also prevent the slope of the part of the sidewall of the pit 31 that is inclined relative to the bottom surface from being too large due to the ratio being too small (i.e., L is small when h is constant), which leads to the strong blocking effect of the internal space surrounded by the sidewall and bottom surfaces when the carrier gas used to deposit the passivation layer enters the pit.

It should be noted that the length L of the sidewall of the pit 31 can be determined by taking a cross-section of the pit 31 along the thickness direction of the silicon wafer substrate 10, and the length of the corresponding cross-sectional section on the sidewall is the length L of the sidewall of the pit 31. In the case where there is no textured structure (e.g., pyramid structure) on the sidewall and the bottom surface of the pit 31, the length L of the sidewall of the pit 31 may be the length between any point on the bottom surface and a point opposite to the opening along the extension direction of the sidewall.

For example, in at least one of the plurality of pits 31, L is greater than 3% of the thickness B of the silicon wafer substrate 10 and less than or equal to ten times of the thickness B of the silicon wafer substrate 10. For example, L can be 4%, 20%, 30%, 50%, twice, four times, six times, eight times, or ten times of the thickness of the silicon wafer substrate 10. It can be understood that in the pit 31, with B fixed, the larger the value of the length L of the sidewall, the smaller the slope of the part of the sidewall of the pit that is inclined relative to the bottom surface. Based on this, when the length L of the sidewall of at least one pit 31 is within the above range, it is beneficial to prevent the slope of the part of the sidewall of the pit 31 that is inclined relative to the bottom surface from being too small due to excessive L, which may cause the lateral size of a single pit to be too large. It is also beneficial to set a larger number of pits on the first and/or second surface, and to make the first and/or second surface have a higher trapping effect on large angle incident light. In addition, it can also prevent the slope of the inclined part of the pit sidewall relative to the bottom surface from being too large due to L being too small, which leads to strong obstruction caused by the internal space enclosed by the sidewall and bottom surfaces when the carrier gas used to deposit the passivation layer enters the pit 31.

As for the thickness B of the silicon wafer substrate, it can be set according to actual needs. For example, the thickness B of the silicon wafer substrate can be greater than or equal to 50 microns and less than or equal to 150 microns. For example, the thickness B of the silicon wafer substrate can be 50 microns, 60 microns, 80 microns, 100 microns, 120 microns, 140 microns, or 150 microns.

In some embodiments, the plurality of pits 31 provided on the first and/or second surface may be multiple independent hole type light trapping structures, that is, they are not connected to each other. The size of the hole type light trapping structure is approximately the same in different directions parallel to the first and/or second surface. In addition, different hole type light trap structures can be arranged in a regular array or distributed irregularly.

In other embodiments, the plurality of pits 31 may also be groove type light trapping structures that extend along the first direction and are spaced apart along the second direction. The first direction intersects with the second direction. The length of the groove type light trapping structure along the first direction is greater than its width along the second direction. The first direction and the second direction can be any two directions that are parallel to the first surface and/or the second surface and are different from each other.

It is worth noting that the hole type light trap structure is beneficial for reflecting incident light from various directions to the silicon wafer substrate 10, thereby improving the light absorption rate of the silicon wafer substrate 10. For groove type trap structures, within a certain length along the first direction, the groove type trap structure is relatively flat, which is conducive to improving the quality and passivation effect of the passivation layer on the first and/or second surface, and reducing the carrier recombination rate. In some application scenarios, there is more incident light in a certain direction, so the groove type light trap structure can be used to absorb the incident light in that direction, in order to improve the absorption rate of light in that direction. The specific shape of the pit can be set according to actual needs.

In some embodiments, as shown in FIG. 7, in the case where the textured structure includes pyramid and/or inverted pyramid structures, in at least one of the plurality of pits 31, there is no pyramid and/or inverted pyramid structures on a part of the sidewall, the part of the sidewall being parallel to a sidewall of at least one pyramid and/or inverted pyramid structures on the other part of the sidewall. Specifically, the part of the sidewall without a textured structure may be parallel to a sidewall of the textured structure set on other part of the sidewall of the pit 31. Alternatively, in a case where textured structures are also provided on the bottom surface of at least one pit 31, the part of the sidewall without a textured structure may also be parallel to a sidewall of the textured structure provided on the bottom surface of the pit 31. Alternatively, the part of the sidewall without a textured structure may also be parallel to a sidewall of the textured structure provided on the first region 20.

In at least one of the pits 31, the specific direction of the part of the sidewall without a textured structure can be determined based on the specific size ratio of the textured structure.

For example, in at least one of the pits 31, the part of the sidewall without a textured structure is coplane with a [111] crystal plane. In this case, the sidewall with a crystal orientation of [111] is an atomic level plane. Therefore, when the surface of the part of the sidewall without a textured structure is the [111] crystal orientation plane, the passivation layer can be fully in contact with the atoms that make up the surface, improving the passivation effect of the passivation layer on the surface of that area.

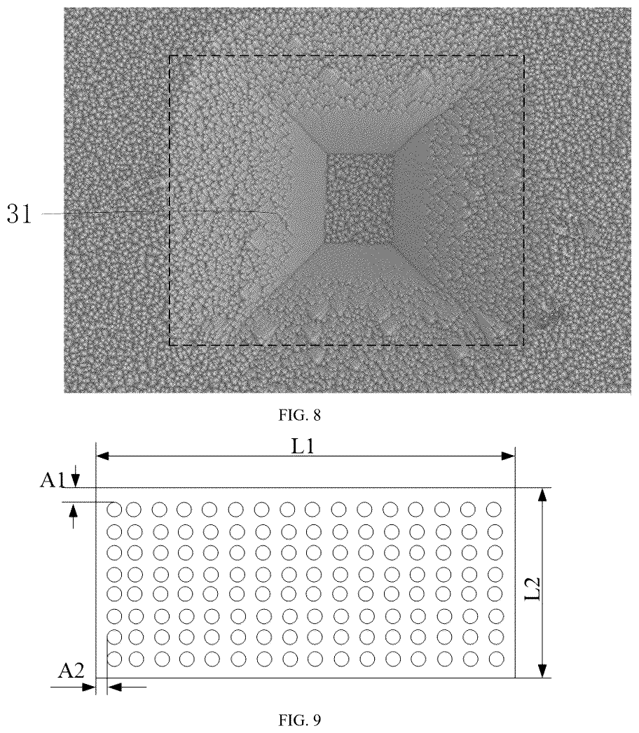

In some embodiments, as shown in FIG. 8, among all the textured structures on the sidewall of at least one pit 31 along the extension direction of the sidewall of the pit 31, the one-dimensional size of the textured structure far from the bottom surface (i.e. close to the opening of the pit 31) is smaller than the one-dimensional size of the textured structure close to the bottom surface. Specifically, it can be that the maximum one-dimensional size of the textured structure far from the bottom surface is smaller than the minimum one-dimensional size of the textured structure close to the bottom surface. It may also be that within a predetermined area (e.g., 5 um² or 10 um²), the maximum one-dimensional size of the textured structure far from the bottom surface is smaller than the maximum one-dimensional size of the textured structure close to the bottom surface. It may also be that within a predetermined area (e.g., 5 um² or 10 um²), the average one-dimensional size of different textured structures far from the bottom surface is smaller than the average one-dimensional size of different textured structures close to the bottom surface. Based on this, the one-dimensional size of the textured structure far from the bottom surface in all the textured structures on the sidewall of at least one pit 31 along the extension direction of the side wall of the pit 31 is set to a smaller value, which is conducive to making the surface roughness of the area close to the opening in the side of the pit 31 relatively small and relatively flat, thereby making the transition between the opening of the pit 31 and the main surface of the first and/or second surface (i.e. the surface of the area without the pit 31 on the first and/or second surface) more gentle, effectively relieving the thin film stress of the passivation layer here, avoiding the risk of warping and other deformations of the passivation layer, and facilitating better adhesion of the passivation layer to the opening of the pit 31 and the first surface.

Alternatively, in the extension direction of the sidewall of the pit 31, among all the textured structures on the sidewall of at least one pit 31, the one-dimensional size of the textured structure away from the bottom surface may also be equal to the one-dimensional size of the textured structure close to the bottom surface.

Referring to FIG. 9, a silicon wafer substrate 10 is further provided according to the embodiments of the present disclosure. The silicon wafer substrate 10 has a first surface and a second surface. The first surface has a first edge and a second edge. The length of the first edge is L1, and the length of the second edge is L2. L1≥L2. The first surface is rectangular or approximately rectangular, and the edge region includes a first edge region and a second edge region intersecting with the first edge region. The first edge region is defined along the first edge, and it can be considered that the extension direction of the first edge region is roughly parallel to the first edge. The second edge region is defined along the second edge, and it can be considered that the extension direction of the second edge region is roughly parallel to the second edge.

The width of the first edge region is A1, and the direction in which the width direction of the first edge region is perpendicular to the extension direction of the first edge.

In the related art, the main reason for the poor mechanical strength of silicon wafer substrates caused by openings in transparent or semi-transparent photovoltaic products is that: in related art, the edges of silicon wafer substrates are not provided with blank regions without openings in transparent or semi-transparent photovoltaic products. Alternatively, for transparent or semi-transparent photovoltaic products, although there are blank regions at the edges of the silicon wafer substrate, the size of the blank regions does not consider the different surfaces, long and short edges, thickness, and material relationships of the silicon wafer substrate, resulting in poor mechanical strength of the silicon wafer substrate.

In response to the above technical issues, for the silicon wafer substrate 10 provided according to the present disclosure, 0.05≤A1/B≤40. Firstly, for the silicon wafer substrate 10 with pits, fracture or breakage is more likely to occur in the first edge region containing the first edge (longer edge) on the first surface. Therefore, in the present disclosure, the focus is on the width of the first edge region on the first surface. Secondly, the thickness B of the silicon wafer substrate 10 is within a certain range. When B is small, the toughness of the silicon wafer substrate 10 with pits 31 is improved, and the brittleness of the silicon wafer substrate 10 with pits 31 is reduced. When B is large, the toughness of the silicon wafer substrate is reduced, and the brittleness of the silicon wafer substrate is increased. When the toughness of the silicon wafer substrate 10 is high, the probability of fracture or breakage will also decrease. That is to say, within a certain range, there is a clear correlation between the B of the silicon wafer substrate and the probability of fracture or breakage of the silicon wafer substrate 10, and the thickness B and electrical effects of the silicon wafer substrate 10 also have important correlations. Considering the factors mentioned above, when the width A1 of the first edge region in the first surface is less than 0.05B, A1 is too small, and the pits 31 in the first surface is too close to the first edge, the risk of fracture or breakage of the silicon wafer substrate 10 in the first edge region containing the first edge is higher. At the same time, compared to A1, the thickness B of the silicon wafer substrate 10 is too large, and the silicon wafer substrate 10 with excessive thickness can lead to excessive electrical losses in the cell body and the edges, resulting in a significant decrease in photoelectric conversion efficiency, When A1 is less than 0.05B, it is too small to ensure the processing parameters of the pits 31 and the yield of the pits 31 is also low. Therefore, when 0.05B≤A1, the width of A1 is suitable. The first edge region of the silicon wafer substrate, including the first edge, on the first surface of the silicon wafer substrate 10 has little risk of breakage or fracture, significantly improving the mechanical strength of the silicon wafer substrate 10. The yield of the pits 31 is high, making it easy to achieve mass production and ensuring the photoelectric conversion efficiency of the photovoltaic cell. Considering the factors mentioned above, in the case where the width A1 of the first edge region in the first surface is greater than 40B, A1 is excessive, and the distance between the pits 31 in the first surface and the first edge of the silicon wafer substrate 10 is too far, resulting in poor transparency and visual effects. Moreover, compared to A1, the thickness B of the silicon wafer substrate is too small, and the mechanical strength and electrical effects of the silicon wafer substrate 10 are difficult to guarantee. Therefore, in the present disclosure, A1≤40B is the result of optimizing and balancing multiple factors including transparency, visual effect, mechanical strength and electrical effect of the silicon wafer substrate. Not only the transparency effect, visual effect, and mechanical strength of the silicon wafer substrate are desirable, but also the electrical effect is good. Furthermore, in the silicon wafer substrate provided in the present disclosure, 0.5≤A1/B≤20.

In some embodiments of the present disclosure, for the photovoltaic cell with double-sided electrodes, the first region and the second region are defined in both the first surface and the second surface of the cell body. The number of the pits 31 between two adjacent electrodes on the light receiving surface is larger than or equal to the number of the pits 31 between two adjacent electrodes on the back surface of the cell body.

In some embodiments of the present disclosure, the pits 31 may be embodied as a through hole penetrating the silicon wafer substrate 10 from the light receiving surface to the back surface of the cell body. The number of through holes between two adjacent electrodes on the light receiving surface is larger than or equal to the number of the through holes between two adjacent electrodes on the back surface of the cell body, which can maximize the light received by the light receiving surface. Therefore, this is an optimized choice considering the carrier collection and power generation efficiency towards the light receiving surface of the photovoltaic cell. It not only ensures the transmittance or visual effect of the double-sided photovoltaic cell, but also ensures the current collection and power generation efficiency towards the light receiving surface of the double-sided photovoltaic cell.

A photovoltaic cell including the above-mentioned silicon wafer substrate 10 is further provided according to the present disclosure.

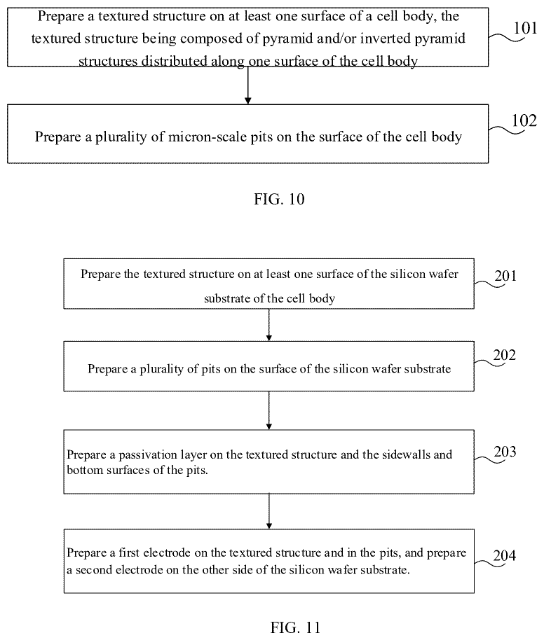

A method for preparing the above-mentioned photovoltaic cell is further provided according to the present disclosure. Referring to FIG. 10, which is a flow chart of a method for preparing a photovoltaic cell provided by an embodiment of the present disclosure, the method may include steps described below.

At step 101, a textured structure is prepared on at least one surface of a cell body, the textured structure being composed of pyramid and/or inverted pyramid structures distributed along one surface of the cell body.

In this step, the textured structure composed of pyramid and/or inverted pyramid structures can be prepared on the cell body through a texturing process.

Specifically, the textured structure is composed of pyramid and/or inverted pyramid structures continuously distributed along one surface of the cell body. The cell body may be prepared from a monocrystalline silicon wafer. Accordingly, the textured structure is a regular pyramid and/or inverted pyramid structure prepared on one surface of the monocrystalline silicon wafer through a texturing process. Alternatively, the cell body may also be prepared from a polycrystalline silicon wafer. Accordingly, the textured structure is an irregular pyramid and/or inverted pyramid structure prepared on one surface of the polycrystalline silicon wafer through a texturing process.

At step 102, a plurality of micron-scale pits are prepared on the surface of the cell body.

In this step, the photoresist can be coated on the surface of the cell body with the textured structure prepared in the above step, and the photoresist is irradiated with a mask plate with a corresponding pattern being used, then the photoresist at the unshielded position can be removed, thereby forming a corresponding pore structure. Next, a deep reactive ion etching process is used to etch at the positions of the above pores, and form multiple pits, the projection size of the pit on the surface of the cell body being 0.5 to 500 microns, the deviation angle between the sidewall of the pit and the thickness direction of the cell body being less than 70 degrees.

Reference is made to FIG. 11, which is a flow chart of a method for preparing a photovoltaic cell with double-sided electrodes provided by an embodiment of the present disclosure, the method may include steps described below.

At step 201, the textured structure is prepared on at least one surface of the silicon wafer substrate of the cell body.

In this step, the silicon wafer substrate may be an n-type silicon wafer substrate prepared from an n-type crystalline silicon wafer, the thickness of the silicon wafer substrate ranges from 50 to 150 microns, and the silicon wafer substrate can be monocrystalline or polycrystalline.

Further, the textured structure composed of pyramid and/or inverted pyramid structures can be prepared on at least one surface of the silicon wafer substrate through a texturing process.

At step 202, a plurality of pits is prepared on the surface of the silicon wafer substrate.

In this step, the photoresist can be coated on the surface of the silicon wafer with the textured structure prepared in the above step, and the photoresist is irradiated with a mask plate with a corresponding pattern being used, then the photoresist at the unshielded position can be removed, thereby forming a corresponding pore structure. Next, a deep reactive ion etching process is used to etch at the positions of the above pores, and form multiple pits, the projection size of the pit on the surface of the cell body being 0.5 to 500 microns, the deviation angle between the sidewall of the pit and the thickness direction of the cell body being less than 70 degrees.

Specifically, the pit may have a circular hole structure with an average aperture of 5 microns, a distance between adjacent pits is 15 microns, and the depth is 0.5 microns.

Moreover, after multiple pits are prepared on the surface of the silicon wafer substrate with the textured structure, a layered PN junction structure layer can be prepared by diffusion on the surface of the textured structure and the sidewalls and bottom surfaces of the pits to separate the carriers.

At step 203, a passivation layer is prepared on the textured structure and the sidewalls and bottom surfaces of the pits.

In this step, the passivation layer can be deposited on the textured structure as well as the sidewalls and bottom surfaces of the pits, for example, the passivation layer can include 2-nanometer-thick silicon oxide, achieving a surface passivation function on one side of the photovoltaic cell.

Further, 70-nanometer-thick silicon nitride can be prepared on the passivation layer to realize the function of anti-reflection on one side of the photovoltaic cell, and the 2-nanometer-thick silicon oxide and the 70-nanometer-thick silicon nitride form a first functional layer with a multilayer structure.

At step 204, a first electrode is prepared on the textured structure and in the pits, and a second electrode is prepared on the other side of the silicon wafer substrate.

In this step, the first electrodes can be prepared on the textured structure and in the pits.

Specifically, a mask may be used to prepare a first hollow structure on the first functional layer, and the first electrode is located at the first hollow structure, so that the first electrode may be disposed on the textured structure or in the pits.

Further, the second functional layer can be deposited on the other side of the silicon wafer substrate, and the second functional layer can be a multilayer structure, for example, the second functional layer can include 2-nanometer-thick silicon oxide, 15-nanometer-thick aluminum oxide, and 50-nanometer-thick silicon nitride, thereby realizing the functions of surface passivation and anti-reflection on the other side of the photovoltaic cell.

Further, the second electrode is prepared on the other side of the silicon wafer substrate. Specifically, a mask may be used to prepare a second hollow structure on the second functional layer, and the second electrode is located at the second hollow structure, so that the second electrode is disposed on the other side of the silicon wafer substrate.

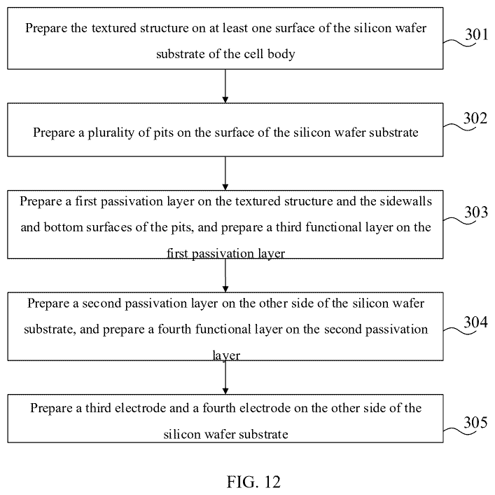

In some embodiments, referring to FIG. 12, which is a flow chart of a method for preparing a photovoltaic cell with single-sided electrodes provided by an embodiment of the present disclosure, the method may include steps described below.

At step 301, the textured structure is prepared on at least one surface of the silicon wafer substrate of the cell body.

In this step, the silicon wafer substrate may be an n-type silicon wafer substrate prepared from n-type crystalline silicon wafer, and the thickness of the silicon wafer substrate may be 100 microns.

Further, the textured structure composed of continuously distributed pyramid and/or inverted pyramid structures can be prepared on at least one surface of the silicon wafer substrate through a texturing process.

At step 302, a plurality of pits is prepared on the surface of the silicon wafer substrate.

In this step, a deep hole with a certain depth can be formed, through a laser ablation process, on the surface of the silicon wafer substrate with the textured structure prepared in the above step, the deep holes can be chemically polished after the laser ablation process to obtain smooth sidewalls and bottom surfaces, thereby preparing multiple pits, the projection size of the pit on the surface of the cell body being 0.5 to 500 microns, the deviation angle between the sidewall of the pit and the thickness direction of the cell body being less than 70 degrees.

Specifically, the pits may have a circular hole structure with an average aperture of 2 microns, a distance between adjacent pits is 5 microns, and the depth is 1 micron.

At step 303, a first passivation layer is prepared on the textured structure and the sidewalls and bottom surfaces of the pits, and a third functional layer is prepared on the first passivation layer.

In this step, the first passivation layer can be prepared on the textured structure as well as the sidewalls and bottom surfaces of the pits, the first passivation layer being amorphous silicon or silicon oxide, thereby realizing the function of surface passivation on one side of the photovoltaic cell.

Further, the third functional layer can be prepared on the first passivation layer, the third functional layer being a multilayer structure, for example, a multilayer silicon nitride structure with a total thickness of 70 nanometers, thereby realizing the functions of surface field passivation and anti-reflection on one side of the photovoltaic cell.

At step 304, a second passivation layer is prepared on the other side of the silicon wafer substrate, and a fourth functional layer is prepared on the second passivation layer.

In this step, the second passivation layer can be prepared on the other side of the silicon wafer substrate, the second passivation layer can also be amorphous silicon or silicon oxide, thereby realizing the function of surface passivation on the other side of the photovoltaic cell.

Further, the fourth functional layer can be prepared on the second passivation layer, and the fourth functional layer can realize the functions of surface field passivation and anti-reflection on the other side of the photovoltaic cell.

At step 305, a third electrode and a fourth electrode are prepared on the other side of the silicon wafer substrate.

In this step, the third electrode and the fourth electrode may be provided on the other side of the silicon wafer substrate, thereby forming a photovoltaic cell with single-sided electrodes. Specifically, a mask plate may be used to prepare a third hollow structure on the fourth functional layer, so that the third electrode and the fourth electrode are alternatively arranged in the third hollow structure.

In the embodiment of the present disclosure, a first collection layer and a first transport layer may be arranged between the third electrode and the second passivation layer, the first collection layer being disposed on a side of the second passivation layer facing away from the silicon wafer substrate, the first transport layer being disposed on a side of the first collection layer facing away from the second passivation layer; a second collection layer and a second transport layer are arranged between the fourth electrode and the second passivation layer, the second collection layer being disposed on a side of the second passivation layer facing away from the silicon wafer substrate, the second transport layer being disposed on a side of the second collection layer facing away from the second passivation layer.

Specifically, when an n-type crystalline silicon wafer is used as the silicon wafer substrate, the first collection layer may be a majority carrier collection region composed of n-type doped amorphous silicon, the second collection layer may be a minority carrier collection region composed of p-type doped amorphous silicon. The first collection layer and the second collection layer are alternately arranged on the surface of the second passivation layer on the other side of the silicon wafer substrate, a ratio of the projection area of the first collection layer on the second passivation layer to that of the second collection layer may be 5% to 45%, and an electrical isolation gap is provided between the first collection layer and the second collection layer. Correspondingly, the first transport layer is a carrier transport layer corresponding to the first collection layer, that is, the majority carrier transport layer, and the third electrode is a majority carrier terminal electrode of a photovoltaic cell with single-sided electrodes; the second transport layer is a carrier transport layer corresponding to the second collection layer, that is, the minority carrier transport layer, and the fourth electrode is the minority carrier terminal electrode of the photovoltaic cell with single-sided electrodes. In addition, the first collection layer and the second collection layer may also use doped polysilicon material.

It should be noted that, for the sake of simple description, the method embodiment is expressed as a series of action combinations, but those skilled in the art should know that the embodiment of the present disclosure is not limited by the described action order, according to the embodiments of the present disclosure, certain steps may be performed in other orders or simultaneously. Moreover, those skilled in the art should also know that the embodiments described in the specification are all preferred embodiments, and the actions involved are not necessarily required by the embodiments of the present disclosure.

In addition, the present disclosure further provides a photovoltaic module composed of the above photovoltaic cells.

It should be noted that, the terms “comprising”, “including” or any other variation thereof as used herein are intended to cover a non-exclusive inclusion, such that a process, method, article or apparatus including a set of elements includes not only those elements, but also other elements not expressly listed, or elements inherent in the process, method, article, or apparatus. Without further limitations, an element defined by the phrase “comprising a . . . ” does not preclude the presence of additional identical elements in the process, method, article, or apparatus including that element.

The embodiments of the present disclosure have been described above in conjunction with the accompanying drawings, but the present disclosure is not limited to the above-mentioned specific implementations, which are only illustrative and not restrictive. Under the inspiration of the present disclosure, those skilled in the art can also make many forms without departing from the purpose of the present disclosure and the protection scope of the claims, all of which belong to the protection of the present disclosure.

What is claimed is:

1. A photovoltaic cell, comprising:
a cell body, wherein at least one surface of the cell body comprises a first region and a second region that are not overlapped with each other, wherein the first region has a textured structure, and wherein the textured structure comprises one or more of pyramid or inverted pyramid structures, and wherein the second region comprises a plurality of pits.

2. The photovoltaic cell according to claim 1, wherein a projection size of each of the plurality of pits on the surface of the cell body is 0.5 to 500 microns; or
a deviation angle between a sidewall of each of the plurality of pits and a thickness direction of the cell body is between 0 and 70 degrees.

3. The photovoltaic cell according to claim 1, wherein the plurality of pits are distributed in an array on the surface of the cell body; and
a space between adjacent pits in the plurality of pits is greater than or equal to 0 micron, and less than or equal to 300 microns.

4. The photovoltaic cell according to claim 1, wherein a ratio of a projection area of the plurality of pits on the surface of the cell body to a surface area of the cell body is between 0.4 and 0.95.

5. The photovoltaic cell according to claim 1, wherein depths of the plurality of pits are greater than or equal to 0.1 microns.

6. The photovoltaic cell according to claim 1, wherein the plurality of pits comprise one or more of round holes, rectangular holes, or holes with irregular shapes.

7. The photovoltaic cell according to claim 1, further comprising:
a silicon wafer substrate, wherein the silicon wafer substrate has a thickness between 50 and 150 microns.

8. The photovoltaic cell according to claim 7, further comprising:
a first electrode arranged on a side of the silicon wafer substrate, wherein the first electrode being at least partially disposed on the textured structure.

9. The photovoltaic cell according to claim 8, wherein the first electrode comprises a first main grid and a first fine grid, the first main grid being disposed on at least one of the textured structure and the plurality of pits, and the first fine grid being disposed on the textured structure.

10. The photovoltaic cell according to claim 1, further comprising:
a passivation layer disposed on: (1) the textured structure, and (2) bottom surfaces and sidewalls of the plurality of pits.

11. The photovoltaic cell according to claim 1, wherein the photovoltaic cell is a photovoltaic cell with single-sided electrodes, and wherein the cell body comprises:
a silicon wafer substrate;
a first passivation layer and a first functional layer arranged on a side of the silicon wafer substrate; and
a second passivation layer, a second functional layer, a first electrode and a second electrode arranged on the other side of the silicon wafer substrate.

12. The photovoltaic cell according to claim 11, wherein a first collection layer and a first transport layer are arranged between a third electrode and the second passivation layer, the first collection layer is disposed on a side of the second passivation layer facing away from the silicon wafer substrate, and the first transport layer is disposed on a side of the first collection layer facing away from the second passivation layer; and
wherein a second collection layer and a second transport layer are arranged between a fourth electrode and the second passivation layer, the second collection layer is disposed on the side of the second passivation layer facing away from the silicon wafer substrate, and the second transport layer is disposed on a side of the second collection layer facing away from the second passivation layer.

13. The photovoltaic cell according to claim 10, wherein:
a thickness of a part of the passivation layer on the sidewalls of the plurality of pits is H1, a thickness of a part of the passivation layer on the bottom surfaces of the plurality of pits is H2, and a thickness of a part of the passivation layer on the first region is H3;
H2 for at least one position is greater than H1 for at least one position; or
H3 for at least one position is greater than H1 for at least one position.

14. The photovoltaic cell according to claim 1, wherein each of the plurality of pits has a bottom surface and a sidewall surrounding the bottom surface, and at least a part of the sidewall is inclined relative to the bottom surface; wherein a maximum size of an opening of the plurality of pits is W1, a maximum size of the bottom surface of the plurality of pits is W2, and a maximum depth of the plurality of pits is h; and
wherein in at least one of the plurality of pits, 0.1≤(W1−W2)/h≤50.

15. The photovoltaic cell according to claim 14, wherein:
a one-dimensional size of the one or more pyramid or inverted pyramid structures is smaller than a one-dimensional size of the plurality of pits;
in at least one of the plurality of pits, one or more pyramid or inverted pyramid structures are located on a part of the sidewall close to the opening and are absent from a part of the sidewall close to the bottom surface; or
in at least one of the plurality of pits, each side wall has one or more pyramid or inverted pyramid structures.

16. The photovoltaic cell according to claim 14, wherein:
a one-dimensional size of a part of the one or more pyramid or inverted pyramid structures on the sidewall in at least one of the plurality of pits is D2;
a one-dimensional size of a part of the one or more pyramid or inverted pyramid structures on the bottom surface in at least one of the plurality of pits is D1, where D2>D1; or
a one-dimensional size of the one or more pyramid or inverted pyramid structures in the first region is D3, where D2>D3.

17. The photovoltaic cell according to claim 16, wherein along an extension direction of the sidewall of each of the plurality of pits, among the pyramid or inverted pyramid structures corresponding to the sidewall of at least one of the plurality of pits, a one-dimensional size of the one or more pyramid or inverted pyramid structures away from the bottom surface is smaller than a one-dimensional size of the one or more pyramid or inverted pyramid structures close to the bottom surface.

18. The photovoltaic cell according to claim 14, wherein in at least one of the plurality of pits, no pyramid or inverted pyramid structure is located on a part of the sidewall parallel to a sidewall with the one or more pyramid or inverted pyramid structures.

19. The photovoltaic cell according to claim 7, wherein:
the cell body has a first surface and a second surface, the first region and the second region being in the first surface, the first surface having a first edge and a second edge, wherein a length of the first edge is L1, a length of the second edge is L2, L1≥L2;
a region without the plurality of pits is an edge region, the edge region including a first edge region along the first edge and a second edge region along the second edge; and
a width of the first edge region is A, and a thickness of the silicon wafer substrate is B, wherein 0.05≤A/B≤40.

20. A photovoltaic module comprising a photovoltaic cell, wherein the photovoltaic cell comprises:
a cell body, wherein at least one surface of the cell body comprises a first region and a second region that are not overlapped with each other, wherein the first region has a textured structure, and wherein the textured structure comprises one or more of pyramid or inverted pyramid structures, and wherein the second region comprises a plurality of pits.
